(19) United States
(12) Patent Application Publication
(10) Pub. No.: US 2007/0042532 A1
(43) Pub. Date: Feb. 22, 2007

(54) System and methods for packing in turnkey services

(75) Inventors: Jung-Yi Tsai, Hsinchu City (TW); Chao-Hsin Chang, Hsin-Chu City (TW); Wen-Sze Huang, Pingjhen City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Taiwan Semiconductor Manufacturing Co., Ltd.

(21) Appl. No.: 11/208,102

(22) Filed: Aug. 19, 2005

(51) Int. Cl. H01L 21/00

(52) U.S. Cl. 438/113

(57) ABSTRACT

A system of packing for turnkey services. An input port receives first and second wafer lots from a semiconductor manufacturer. The first wafer lot comprises a first number of dies, and the second wafer lot comprises a second number of dies. A packing device loads dies of the first wafer lot in a provided carrier having a preset capacity, and each of the loaded carriers is filled to capacity. A controller determines whether there is a remaining die of the first wafer lot that cannot fill one of the carriers, and directs the packing device to load the remaining dies of the first wafer lot and dies of the second wafer lot sequentially.

### BACKGROUND

The invention relates generally to semiconductor manufacture, and more particularly to die packing in a turnkey service.

For shipment of dies, customers generally have a choice of waffle packs, Gel Packs, or sawn wafers shipped on sticky tape supported by a film frame. For large volume shipments, dies can be provided in a tape & reel mechanism using either Surf Tape or embossed pocket tape. The tape & reel mechanism is ideal for high volume applications, wherein dies are securely held by tape, and tape of a particular width can fit multiple die sizes. For example, a tape with 7″ reel width may carry up to 7000 dies, and a tape with 13″ reel width may carry up to 23,000 dies.

A reel and tape used for the tape & reel mechanism are shown in FIG. 1. A plurality of dies 11 are mounted on a carrier tape 12. A cover tape 13 covers the mounted dies 11, providing protection against moisture, mechanical damage, or other damage to the dies. The carrier tape 12 mounted with dies 11 is winded on a reel 14. The number of dies carried on reel 14 varies determined by the die size and tape width. For a particular die size and tape width, the number of dies carried on a reel is fixed.

In shipments, dies of the same lot are typically sorted together, and every reel is loaded to capacity. For a particular lot, the remaining dies that cannot fill up a reel are left in storage. Remaining dies of different lots are then combined and loaded on to reels periodically. For example, as shown in FIG. 2, lots A, B, and C comprise 12005, 12315, and 12595 dies, respectively. Here, each reel can carry up to 500 dies. Each lot A, B, and C fill up 24 reels, respectively. The remaining dies unfilled from lots A, B, and C are 5, 315, and 95 dies, respectively. Conventionally, the remaining dies of lots A, B, and C are pooled together for reel-packing. Among the 915 remaining dies, 500 dies fill another reel and 415 dies are left in storage. The filled reels are shipped to a customer. The reel containing mixed dies of lots A˜C may cause management difficulty for the customer.

### SUMMARY

The present invention provides a system of packing for turnkey services, comprising an input port, a packing device, and a controller. The input port receives first and second wafer lots from a semiconductor manufacturer. The first wafer lot comprises a first number of dies, and the second wafer lot comprises a second number of dies. The packing device loads dies of the first wafer lot in a provided carrier having a preset capacity, and each of the loaded carriers is filled to capacity. The controller determines whether there is remaining die of the first wafer lot that cannot fill one of the carriers, and directs the packing device to load the remaining dies of the first wafer lot and dies of the second wafer lot sequentially.

The invention also provides a method of packing. First, a plurality of carriers are provided, each of which has a preset capacity. A first wafer lot is provided, comprising a first number of dies. Dies of the first wafer lot are loaded in the carriers, wherein each of the loaded carriers is filled up to its capacity. It is determined whether there is a remaining die of the first wafer lot that cannot fill one of the carriers. A second wafer lot is then provided, comprising a second number of dies. If the remaining die exists, the remaining die of the first wafer lot and dies of the second wafer lot are loaded in the carriers sequentially. If the remaining die does not exist, the dies of the second wafer lot are loaded.

A method of turnkey service is also provided. First and second wafer lots are provided, comprising first and second number of dies, respectively. Identification information corresponding to the first and second wafer lots is received. Dies of the first wafer lot are loaded in at least one tape-on-reel having a preset capacity, wherein each of the loaded reels is filled up to its capacity. It is determined whether there is remaining die of the first wafer lot that cannot fill up one of the reels. If the remaining die exists, the remaining die of the first wafer lot and dies of the second wafer lot are loaded in one of the reels sequentially. Each of the loaded reels is assigned an identification number according to the source of the dies loaded therein.

### DESCRIPTION OF THE DRAWINGS

The invention can be more fully understood by reading the subsequent detailed description and examples with references made to the accompanying drawings, wherein:

FIG. 1 is a schematic view of a tape & reel used in a conventional packing system;

FIG. 2 is an embodiment of operation of a conventional packing system;

FIG. 3 is a schematic view of an exemplary embodiment of a supply chain system of the invention;

FIG. 4 is a schematic view of an exemplary embodiment of an operation system implemented in a subcontractor operation of FIG. 3;

FIGS. 5A and 5B are flowcharts of an exemplary embodiment of a method for packing in a turnkey service.

### DETAILED DESCRIPTION

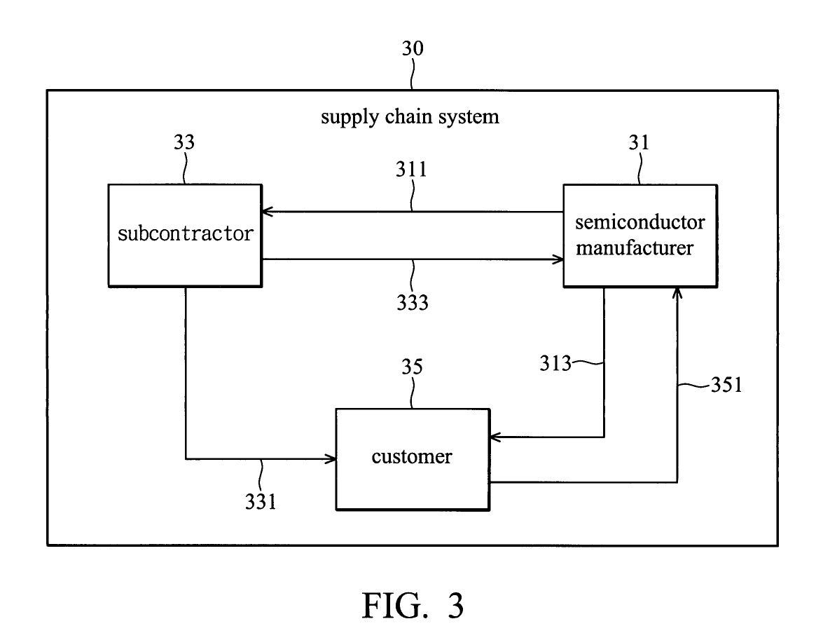

Exemplary embodiments of the invention will now be described with reference to FIGS. 3 through 5, which generally relate to performing turnkey services in a manufacturing environment.

In the following detailed description, reference is made to the accompanying drawings which form a part hereof, and in which is shown by way of illustration of specific embodiments. These embodiments are described in sufficient detail to enable those skilled in the art to practice the invention, and it is to be understood that other embodiments may be utilized and that structural, logical and electrical changes may be made without departing from the spirit and scope of the present invention. The following detailed description is, therefore, not to be taken in a limiting sense. The leading digit(s) of reference numbers appearing in the Figures corresponds to the Figure number, with the exception that the same reference number is used throughout to refer to an identical component which appears in multiple Figures.

FIG. 3 is a schematic view of an exemplary embodiment of a supply chain system 30 comprising a semiconductor manufacturer 31, a subcontractor 33, and a customer 35. Specifically, customer 35 places an order for semiconductor products to the semiconductor manufacturer 31. The semiconductor manufacturer 31 offers a turnkey service that accepts a prime design 351 in GDS-II format from the customer 35 and provides wafer manufacture, test, and/or assembly of finished devices. The semiconductor manufacturer 31 fabricates wafers for the ordered products, and the processed wafers 311 are further processed and packaged by the subcontractor 33. After the dies obtained from the wafer are loaded in at least one tape-on-reel, the loaded reels 331 are shipped to the customer 35. Additionally, the subcontractor 33 assigns the loaded reel 331 an identification number according to the source of the dies loaded therein. The subcontractor 33 provides notification information 333 to the semiconductor manufacturer 31, comprising the identification number of the loaded reels 331 corresponding to wafer lots 311. The semiconductor manufacturer 31 receives the notification information 333, incorporates it into information pertaining to a corresponding purchase order, generates a report 313 accordingly, and sends the report 13 to the customer 35. The customer 35 receives the report 313, and checks and accepts the loaded reels 331 accordingly.

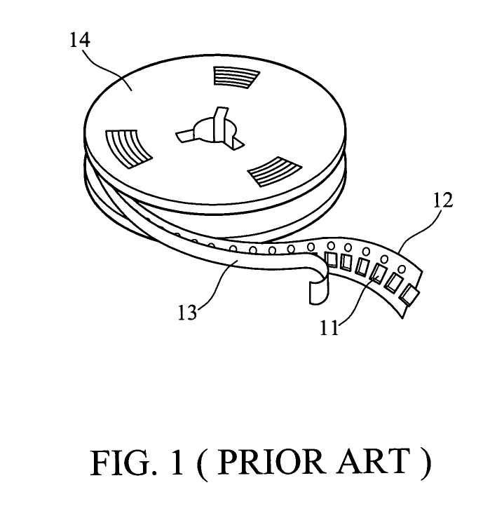

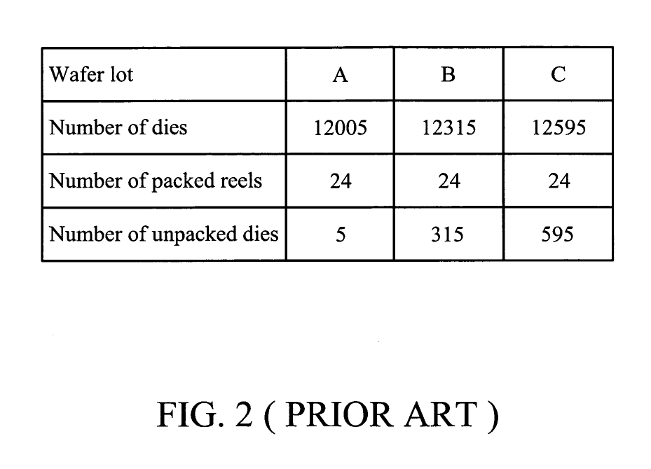

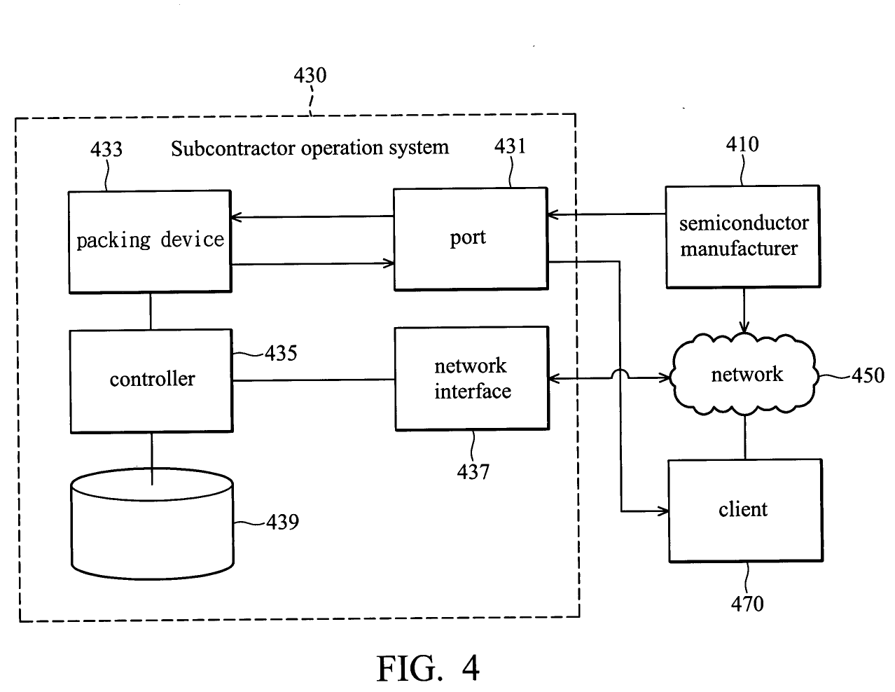

FIG. 4 is a schematic view of an exemplary embodiment of an operation system implemented in a subcontractor operation of FIG. 3. Subcontractor operation system 430 comprises a port 431, a packing device 433, a controller 435, and a network interface 437. The subcontractor system 430 receives wafer lots from a semiconductor manufacturer 410, and sends reels loaded with packaged dies of the wafer lots to a client 470. The wafer lots and the loaded reels are transported via the port 431. Here, the port 431 receives first and second wafer lots comprising a first and second number of dies, respectively. The subcontractor operation system 430 communicates with the semiconductor manufacturer 410 via the network interface 437 and a network 450. The network interface 437 receives a work order corresponding to the first and second wafer lots from the semiconductor manufacturer 410. The packing device 433 loads dies of the first wafer lot in a carrier having a predetermined capacity, and each of the loaded carriers is filled to capacity. The controller 435 determines whether there is a remaining die of the first wafer lot that cannot fill one of the carriers, and directs the packing device 433 to load the remaining die of the first wafer lot and dies of the second wafer lot sequentially. Here, the carrier is a tape-on-reel similar to or as that illustrated in FIG. 1. The controller 435 further assigns the loaded carrier an identification number according to the source of the dies loaded therein. For example, when the carrier is loaded with dies of the same wafer lot, the controller 435 further assigns the identification number according to identification information of the wafer lot; when the carrier is loaded with dies of multiple wafer lots, the controller 435 assigns the identification number to indicate that the carrier contains multiple lots. For instance, the identification number may be assigned as the combination of identification information of the wafer lots. The identification number may be assigned according to a rule predetermined by the semiconductor manufacturer 410. The identification number and other relative information of the loaded reels are then transmitted to the semiconductor manufacturer 410 through the network interface 437. The semiconductor manufacturer 410 generates notification information according to the information received from the subcontractor operation system 430, and sends the notification information to the client 470. The loaded reels are transported to the client 470 via the port 431, wherein the client 470 has placed an order to the semiconductor manufacturer 410, and the order corresponds to the first and second wafer lots. The client 470 accepts the loaded reels and checks them according to the notification information received from the semiconductor manufacturer 410.

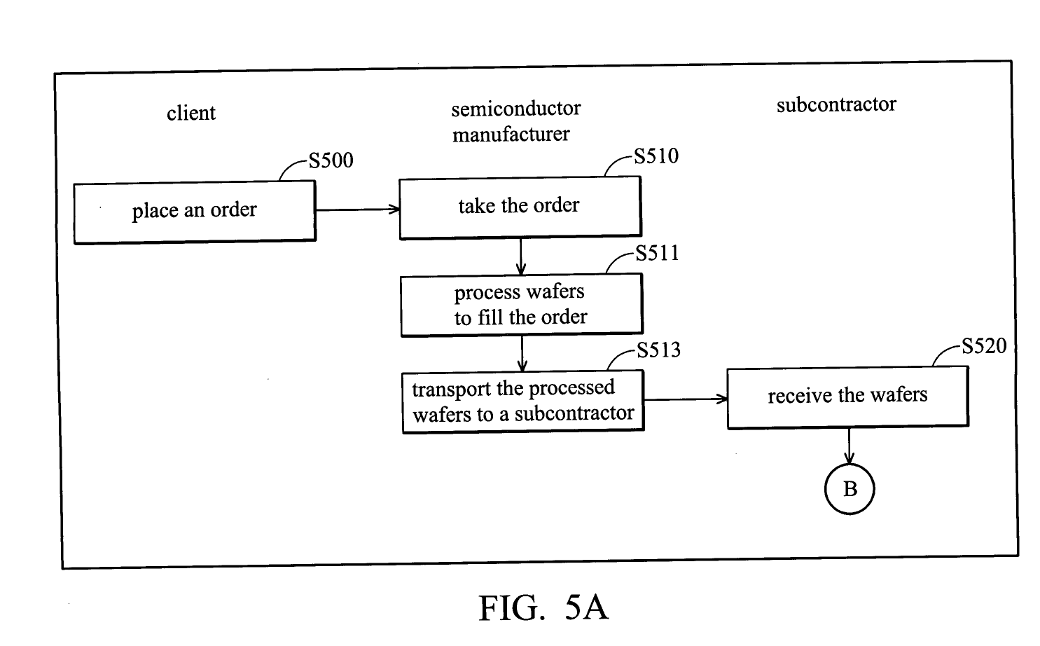

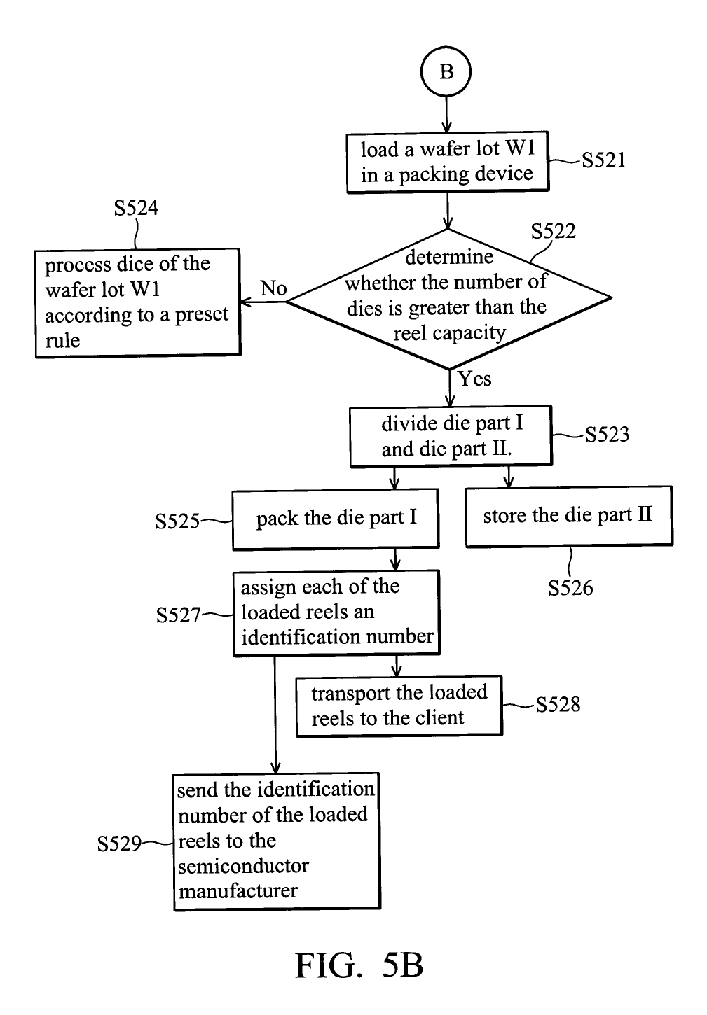

FIGS. 5A and 5B are flowcharts of an embodiment of a method for packing in a turnkey service. Referring to FIG. 5A, an order is placed by a client in step S500. The order is taken by a semiconductor manufacturer in step S510. In step S511, wafers are processed to fill the order. In step S513, the processed wafers are transported to a subcontractor for further processing. When the subcontractor receives the wafers (step S520), the method proceeds to process B. Referring to FIG. 5B, a wafer lot W1 is loaded in a packing device (step S521). The packing device packs dies of the wafer lot W1 on a tape and winds the tape on a reel. Here as an example, each reel carries a load of 500 dies. It is determined whether or not the number of dies obtained from the wafer lot W1 is greater than the reel capacity, i.e., 500 dies (step S522), and if so, the operation proceeds to step S523, otherwise to step S524. In step S524, dies of the wafer lot W1 is processed according to a predetermined rule. For example, dies of the wafer lot W1 may be packed with dies of a previous wafer lot or a following wafer lot. The preset rule may be determined to meet special requirements. The preset rule may be set according to requirements of the semiconductor manufacturer or the client. In step S523, dies that can fill the reel (hereinafter referred to as die part I) are obtained from the wafer lot W1, and the remaining dies, if presents, is referred to as die part II. The die part I is further processed in step S525, and the die part II is processed in step S526. In step S525, the die part I is packed in at least one reel, depending on the number of dies thereof. In step S526, the die part II is temporarily stored, waiting for dies of a following wafer lot to be packed in a carrier of a multiple wafer lots. In step S527, each of the loaded reels is assigned with an identification number according to identification information of the wafer lot W1. In step S528, the loaded reels are transported to the client. In step S529, the identification number of the loaded reels is sent to the semiconductor manufacturer via network or other suitable means, and the semiconductor manufacturer transfers the identification number together with information pertaining to corresponding order to the client, thus the client can verify and accept the loaded reel accordingly.

For example, there are three wafer lots corresponding to an order placed by the client, wherein wafer lots A, B, and C comprise 12005, 12315, and 12595 dies, respectively. Here, for example, each reel can carry 500 dies. The wafer lot A fills up 24 reels, with 5 remaining dies unpacked. The reel comprises dies of wafer lot A is assigned an identification number according to the identification number of wafer lot A. Here, the identification number of wafer lot A is ‘9K12345.00’, and the reel comprising dies of the wafer lot A is assigned an identification number of ‘9K12345.00’. The remaining dies of wafer lot A are combined with dies of the wafer lot B, and packed in at least one of the reels. Here, 495 dies are separated from the wafer lot B, and combined with the 5 remaining dies of the wafer lot A to fill up a reel. And the other 11820 dies of wafer lot B fill up 23 reels, with 320 remaining dies. The reel comprises dies of both wafer lot A and B is assigned an identification number according to the identification numbers of wafer lots A and B. Here, the identification number of wafer lot B is ‘RK56789.11’. Therefore, the identification of the reel comprising dies of both wafer lots A and B is ‘RK56789119K1234500’, wherein the ‘RK5678911’ is derived from the identification number of wafer lot B and the ‘9K1234500’ from wafer lot A. The identification number of the wafer lot with a greater contribution may be used as the first 9 numbers of the identification code of the reel. Here, the reel ‘RK56789119K1234500’ comprises 5 dies of the wafer lot A, and 495 dies of the wafer lot B, thus the identification thereof is initiated with the identification number of the wafer lot B. The remaining dies of wafer lot B are combined with dies of the wafer lot C, and packed in at least one of the reels. Here, 180 dies are obtained from the wafer lot C, and combined with the 320 remaining dies of the wafer lot B to fill a reel. The other 12415 dies of wafer lot B fill 24 reels, with 415 remaining dies. The reel comprises dies of both wafer lot B and C is assigned an identification number according to the identification numbers of wafer lots B and C. Here, the identification number of wafer lot C is ‘RK23456.00’. Therefore, the identification of the reel comprising dies of wafer lots B and C is ‘RK5678911RK2345600’, wherein the ‘RK2345600’ is derived from the identification number of wafer lot C and the ‘RK5678911’ from wafer lot B. As described, the identification number of the wafer lot with a greater contribution may be used as the first 9 numbers of the identification code of the reel. Here, the reel ‘RK5678911RK2345600’ comprises 320 dies of the wafer lot B, and 180 dies of the wafer lot C, thus the identification thereof is initiated with the identification code of the wafer lot B. When the reel comprises an equal number of dies from two wafer lots, the identification number of the reel is initiated with the identification number of the wafer lot which is processed first.

While the invention has been described by way of example and in terms of several embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method of packing, comprising:
providing a plurality of carriers, each of which has a predetermined capacity;
providing a first wafer lot comprising a first number of dies;
loading dies of the first wafer lot in the carriers, wherein each of the loaded carriers is filled to capacity;
determining whether there are remaining dies of the first wafer lot that cannot fill one of the carriers;
providing a second wafer lot comprising a second number of dies; and
loading the remaining dies of the first wafer lot and dies of the second wafer lot sequentially.

2. The method of claim 1, wherein the carrier is a tape-on-reel.

3. The method of claim 1, further determining whether the first number exceeds the preset capacity, and joining the first number of dies to dies of other wafer lots to fill one of the carriers according to a preset rule.

4. The method of claim 1, further determining whether there are remaining dies of a previous wafer lot awaiting packing, and if so, joining the remaining dies of the previous wafer lot with the first wafer lot, and loading the remaining dies of the previous wafer lot with the first wafer lot sequentially in the carrier.

5. The method of claim 1, further assigning the loaded carrier with an identification number according to the source of the dies loaded therein.

6. The method of claim 5, when the carrier is loaded with dies of the same wafer lot, further assigning the identification number according to identification information of the wafer lot.

7. The method of claim 5, when the carrier is loaded with dies of two subsequent wafer lots, further assigning the identification number as the combination of identification information of the wafer lots.

8. The method of claim 1, further transmitting the loaded carriers to a client having ordered the wafer lots.

9. The method of claim 1, further transmitting the identification information of the loaded carriers and corresponding wafer lots to a manufacturer of the wafer lots.

10. A system of packing, comprising:
an input port receiving a first and a second wafer lots comprising a first and a second number of dies, respectively;
a packing device loading dies of the first wafer lot in a carrier with a predetermined capacity, and each of the loaded carriers filled to capacity; and
a controller determining whether there are remaining dies of the first wafer lot that cannot fill one of the carriers, and directing the packing device to load the remaining dies of the first wafer lot and dies of the second wafer lot sequentially.

11. The system of claim 10, wherein the packing device loading dies into a tape-on-reel.

12. The system of claim 10, wherein the controller determines whether the first number exceeds the preset capacity, and joins the first number of dies to dies of other wafer lots to fill one of the carriers according to a preset rule.

13. The system of claim 10, wherein the controller further determines whether there are remaining dies of a previous wafer lot that waits for packing, and if so, joins the remaining dies of the previous wafer lot with the first wafer lot, and loads the remaining dies of the previous wafer lot with the first wafer lot sequentially in the carrier.

14. The system of claim 10, wherein the controller further assigns the loaded carrier with an identification number according to the source of the dies loaded therein.

15. The system of claim 14, when the carrier is loaded with dies of the same wafer lot, the controller further assigning the identification number according to identification information of the wafer lot.

16. The system of claim 14, when the carrier is loaded with dies of two subsequent wafer lots, the controller further assigning the identification number as the combination of identification information of the wafer lots.

17. A method of turnkey service, comprising:
receiving a first and a second wafer lots comprising a first and a second number of dies, respectively, and identification information corresponding to the first and second wafer lots;
loading dies of the first wafer lot in tape-on-reel with a preset capacity, wherein each of the loaded reels is filled up to its capacity;
determining whether there are remaining dies of the first wafer lot that have not been loaded;
loading the remaining dies of the first wafer lot and dies of the second wafer lot sequentially;
assigning the loaded reel with an identification number according to the source of the dies loaded therein.

18. The method of claim 17, when the carrier is loaded with dies of the same wafer lot, further assigning the identification number according to identification information of the wafer lot; when the carrier is loaded with dies of two subsequent wafer lots, further assigning the identification number as the combination of identification information of the wafer lots.

19. The method of claim 17, further transmitting the loaded carriers to a client having ordered the wafer lots.

20. The method of claim 17, further transmitting the identification information of the loaded carriers and corresponding wafer lots to a manufacturer of the wafer lots.
